(19) United States
(12) Patent Application Publication
(10) Pub. No.: US 2003/0102432 A1
(43) Pub. Date: Jun. 5, 2003

(54) Monolithic infrared focal plane array detectors

(75) Inventors: Paul Boieriu, Chicago, IL (US); Renganathan Ashokan, Darien, IL (US); Yuanping Chen, Rockville, MD (US); Jean-Pierre Faurie, Chicago, IL (US); Sivalingam Sivananthan, Naperville, IL (US)

Correspondence Address: Jefferson Perkins, Esquire, Piper Marbury Rudnick & Wolfe, P.O. Box 64807, Chicago, IL, 60664-0807, US

(73) Assignee: EPIR LTD.

(21) Appl. No.: 09/833,363

(22) Filed: Apr. 12, 2001

(51) Int. Cl. G01T 1/24; H01L 27/14

(52) U.S. Cl. 250/338.4; 250/370.13; 438/73

(57) ABSTRACT

An infrared sensing device including a multi-layer II-VI semiconductor material grown by molecular beam epitaxy on a readout circuit fabricated on silicon substrate having a orientation one degree tilted from the (100) direction is provided in this invention. A method to grow single crystalline mercury cadmium telluride multi-layer structure on custom-designed readout circuit (ROIC) is provided. Due to the height difference of more than 15 micron between the two planes containing the detector output gates and the ROIC signal input gates, a mesa with at least one sloped side is fabricated and the interconnecting metal electrodes running on them to connect the detector output to ROIC input. Planar photovoltaic junctions are fabricated selectively on the II-VI mesa structure formed on ROIC. At least one infrared detecting cell being formed in the mesa, with a conductor interconnect layer connecting the detection cell to the readout integrated circuit. Another design to simultaneously produce two linear arrays of monolithic infrared detectors is provided by the suitable design of the ROIC input pads and the infrared detector arrays.

### RELATED APPLICATION

The present application is related to and fully incorporates by reference to application Ser. No. ______, filed MMMM, DD, 2001, Entitled “MULTISPECTRAL MONOLITHIC INFRARED FOCAL PLANE ARRAY DETECTORS”.

### FIELD OF THE INVENTION

The present invention relates to infrared sensing device, and more specifically monolithic infrared imaging arrays based on the direct growth of infrared sensitive mercury cadmium telluride material structure on custom-fabricated read-out electronics on specially oriented silicon substrates.

### BACKGROUND OF THE INVENTION

Semiconductors are either naturally occurring or artificially synthesized materials in which the atomic arrangement gives rise to a specific atomic potential that forbids electrical carries (electrons or positive charges, known as holes) to freely move and therefore carry electrical currents. They act as insulators for as long as there is no additional energy provided to excite these carriers across the forbidden gap (called band gap) that is generated by the atomic potential. An electrical current can be obtained by the excitation of electrons across the forbidden band. Necessary energy can be generated in different ways and of interest for radiation detection is the energy carried by the electromagnetic radiation waves. The incoming radiation has to be tuned (i.e. the radiation has to carry enough energy to be able to excite the electrons) with the band gap of the semiconductor in order to produce this excitation.

In a crystal, both short- and long-range order are important in defining single crystal structure. The atoms hold positions that can be associated with a well-defined grid (or lattice) having very small or nonexistent deviations from the grid positions through out the entire crystal. This periodicity in the atomic arrangement is of utmost importance for the electrical behavior of the crystal. A polycrystalline material has a short-range order, a specific geometrical positioning of the atoms in a lattice, but lacks long-range order. Only by performing a combination of translations and rotations one can recover the same geometrical arrangement of an initial test region.

The polycrystalline material is formed by a multitude of grains consisting of individual single crystals. A long-range order means that by translating the crystal in any direction one recovers exactly the same structural arrangement of the atoms. A unit cell can be therefore defined, and the entire crystal can be regained by translations of this unit cell. An amorphous material lacks both short and long-range order, and consequently lacks any periodicity in its atomic arrangement.

FIG. 1 shows the unit cell for a cubic crystalline lattice and several crystal directions. The crystal planes are planes that contain atoms and are perpendicular to the respective direction. The (100) plane in a cubic lattice is shown as shaded in FIG. 1. Obviously, in the case of a cubic unit cell the chosen orientation of the reference system is arbitrary, thus the (100), (010) and (001) planes are equivalent. All the equivalent planes form a family of planes and are called by a generic name, which is one of the family member names. The atoms can occupy positions on the nodes of the grid or at intersections of principal lines within the unit cell (such as the center of lateral cubic faces or the intersection of body diagonals of the cube). The atoms can, as well, occupy positions at certain coordinates around the nodes or intersections of principal lines in what is called a basis. A cubic unit cell with atoms sitting at the nodal position as well as in the center of each cubic face is called a face centered cubic (fcc). Mercury cadmium telluride (HgCdTe or MCT) is an fcc lattice with a basis in which a secondary set of atoms is situated at ¼ of the cubic length away from the fcc atoms in the (111) direction.

Mercury cadmium telluride is a semiconductor widely used as an infrared detector material. It consists of elements positioned in group II (Hg, Cd) in the periodic table of elements and in group VI (Te). The crystalline MCT is formed as a ternary material from an HgTe (mercury telluride) crystal lattice in which a certain percentage of Hg atoms is being replaced by Cd atoms.

By varying the amounts of Cd atoms in replacement of Hg atoms, the electrical properties of the entire crystal can be tailored to suit the absorption and subsequent conversion of the incident infrared radiation into electrical current. Thus, short wavelength infrared (SWIR) MCT has a Cd percentage that allows radiation absorption of short wavelengths. Similarly, mid-wavelength (MWIR) MCT has a Cd percentage that allows radiation absorption of medium wavelengths, and long wavelength (LWIR) MCT has a Cd percentage that allows radiation absorption of long wavelengths.

The flexibility of matching the electrical behavior of the crystal to certain application requirements by adjusting the composition of the crystal is known as band gap engineering, and is one of the great advantages of MCT. Several techniques are available for producing MCT and by far, MBE is the most reliable.

Molecular beam epitaxy (MBE) is a chemical vapor deposition (CVD) method in which the crystal is grown on a template (substrate) from atomic and/or molecular fluxes obtained by thermal evaporation of the charge material. The growth process occurs in an ultra-high vacuum (UHV) environment to minimize the presence of foreign atoms. Polycrystalline and/or amorphous material are loaded into crucibles and constitute the charge. During the growth, the substrate is kept at predefined temperatures to ensure that sufficient energy is transferred to the surface to achieve specific reactions. The fluxes are adjusted by the temperatures at which the charge materials are kept. In this way the incoming atoms/molecules from the charges have to spend a certain residence time on the surface while traveling/diffusing around in order to find a geometrical position that minimizes the surface energy.

In order to control and to enhance or modify the electrical properties of the materials grown by MBE one can use this method to add certain impurities (dopants) to the primary material. This added control offers a large advantage since it reduces the post growth processing along with the costs and increases the yield factor.

The substrate is of paramount importance for the MBE growth of crystalline materials. Its choice is primarily dictated by the lattice parameters that have to closely match the ones of the intended new material. Exceptions are rare and mismatches create unwanted density of defects/dislocations.

In order to act as a template, the substrate itself should be a single crystal and one has to expose the periodic arrangement of the bulk material. Typically, the bonds between atoms are saturated (i.e. an atom/ion uses all of its available electrons for bond formation with its neighboring atoms). At the surface, the lack of periodicity in the direction perpendicular to the plane forces the atoms lying on the surface to react (use their available electrons) and bond with other elements, different than those present in the bulk of the material. These elements that are present at the surface are called contaminants. Such a surface is useless for the MBE growth of single crystalline materials.

For the growth of MCT one can use as substrate bulk cadmium zinc telluride (CdZnTe) for which lattice matching occurs at a Zn percentage close to 4%. A constant demand for larger area detectors prevents the use of CdZnTe as substrates since they are available in limited sizes only. Bulk CdZnTe is also expensive and brittle reducing further its use in production environments. When using CdZnTe as substrate one is limited by the current device fabrication technology.

The crystals used as substrates (Silicon, CdZnTe and others) are fabricated by cooling a melt of material (pure elements or compounds) in a way that allows crystal formation. Once crystallized, the previously formed ingot is cut into wafers with various orientations. Since the wafer is a single crystal (hence it contains a large number of unit cells, to be viewed as “bricks”) its surface can have various morphologies. The surface orientation of the substrate is very important since the initial nucleation process takes place on it. At this interface between the new crystal and the substrate the defects can be easily generated and they will further propagate through the entire crystal.

A major problem when growing a new crystal is twin formation. Crystal seeds that nucleate at different moments in time and at different locations are uncorrelated. For various surface orientations this correlation/uncorrelation can be beneficial (increasing the probability that only one crystalline orientation will survive throughout the growth process, generating a single crystal) or detrimental (supporting equally various orientations and ending with a polycrystalline material).

A silicon surface that has orientation (001) is almost flat (FIG. 3). Theoretically, it should be flat since integers of unit cells can be fit within the crystal. Other reasons are called upon to explain the surface morphology in this case. The surface energy is minimized by forming terraces. The terrace steps are always +/−1 monolayer from what is called the substrate surface. All the orientations that do not fit an integer number of the unit cell at the surface are bound to form steps, their number increasing with the wafer area. FIG. 2 shows a schematic of a (211) surface.

Mercury cadmium telluride is by far the most sensitive and commonly used material for infrared detectors. Such detectors generate a signal whose magnitude is proportional to the intensity of the incident radiation.

Every object usually has a distribution of ‘hot’ and ‘cold’ regions in it. The image generated by an array of photon detectors consists of white and black contrast corresponding to the hot and cold regions of the object or scene. An infrared imaging device consists of a plurality of photovoltaic diodes (detectors) fabricated on an infrared sensitive material (such as HgCdTe). When used for imaging, the signal generated by each diode has to be collected separately and multiplexed to re-construct an image on the video screen. The photovoltaic detector essentially consists of a junction formed by two dissimilar (p-type and n-type) conductivity regions in the infrared sensitive material as shown in FIGS. 5a and 5b. The incident infrared radiation creates electron and hole pairs, which are collected by the potential difference at the p-n junction leading to the ‘signal’. Also shown in the figure is the energy band diagram corresponding to the p-n junction formed in a heterostructure. The heterostructure means that the band gaps of the two regions (p and n) are different. The narrow band gap side of the junction is the absorber layer whose band gap is tuned to detect the particular wavelength of interest. The band gap of the top layer (p-layer in the FIG. 5b) is more than that of the n-layer. Such p-n junctions formed in a heterostructure reduce the surface-passivation related leakage currents.

Conventionally, the multiplexing electronics used for infrared detectors is fabricated separately on a silicon substrate. Indium metal bumps are then formed on each diode and the plurality of devices on the two different materials is then connected together by a ‘hybridization’ process. These devices operate usually at 77K, the liquid nitrogen temperature, because one way of exciting electrons across the gap is by thermal excitation. This thermal excitation process becomes concurrent to the radiation-induced excitations. In order to reduce it and to reduce its effects (dark current, noise) the detector operates at low temperature. When cooled to this temperature, the two different materials that together form the infrared imaging device (HgCdTe diode and the read-out circuit) expand at different rates. The different coefficients of expansion lead to failure of the indium bump interconnection between the infrared detector and the signal processor, resulting in poor image resolution.

Recently, a monolithic infrared imaging device to solve the problems associated with hybrid type device has been proposed (Japanese Published Patent Application No. Sho. 63-46765), followed by variants of this method (U.S. Pat. No. 5,410,168 and Japanese Patent Application No. Hei. 2-272766) to improve sensitivity and charge collection efficiency. We denote these methods respectively as method-A, method-B and method-C hereinafter.

The cross-sectional view of Method-A is shown in FIG. 16. A first HgCdTe narrow band gap layer 32 and a second HgCdTe wider band gap layer 33 are deposited on the HgCdTe substrate 31. A photodiode 34 is formed by ion implantation or the like in the first HgCdTe layer 32 by partially removing the second HgCdTe layer 33. A signal charge injection layer 42 is formed in the second HgCdTe layer 33 by ion implantation or the like. A charge transfer gate 43, a charge storage gate 44 and a CCD 45 are disposed on the second HgCdTe 33, and are spaced apart therefrom by an insulating film 40.

The surface leakage current in this method is suppressed since both the ends of the p-n junction of the photodiode 34 are covered with wider band gap HgCdTe layer 33. However, the numerical aperture of the infrared detector is reduced since the metal interconnect 41 covers part of the infrared absorbing window 34. Also, the step coverage of the metal interconnect 41 is likely to fail since the two contact regions 34 and 42 are located in different planes.

FIG. 17 is a cross-sectional view of the monolithic device described in Method-B. A first p-HgCdTe narrow band gap layer 33 is buried between the semiconductor substrate 31 and a wider band gap p-HgCdTe layer 32. A photodiode 34 is formed in the first HgCdTe layer 32, and a source diode 38 and a drain diode 37 are formed in the second HgCdTe layer 33 by ion implantation. An electrode 35 connects the photodiode 34 and the drain diode 37. A gate electrode 36 connects the source diode 38 with the drain diode 37. Gate 36, source 38 and drain 37 form a Metal Insulator Semiconductor (MIS) switch 40 which electrical connections are made through an insulator layer 39. In this method, though the ends of the p-n junction 34 are covered with wider band gap HgCdTe layer 33, the infrared receiving top surface involves passivation of the narrow band gap HgCdTe. This increases the surface recombination velocity, resulting in higher leakage currents. Furthermore, the signal carriers can diffuse back into the light receiving region and recombine resulting in the loss of signal.

FIG. 18 is a cross-sectional view of a device according to Method-C. A wider band gap p-type HgCdTe layer 33 of 1 to 2 microns thickness is disposed on a narrow band gap p-type HgCdTe infrared absorber layer 32 having a thickness of about 10 microns. An n-type light receiving region 34 and a high dopant impurity concentration n-type region 47 are formed by ion implantation. A post implant annealing reduces the n-type carrier concentration in region 34 to the order of 10¹⁵ cm⁻³ and extends this region into p-type substrate 32. In this structure, the surface of the light receiving region, both ends of the p-n junctions are disposed in the semiconductor layer with larger band gap 32, thus reducing the recombination of charge carriers at the light receiving region leading to lower leakage currents. However, this method involves fabrication of two back-to-back p-n junctions 47, 48 for the two contacts (p and n) for each detector and relies on the MIS device 26 fabricated on HgCdTe to collect the photo-generated carriers. It is known that an MIS device formed on HgCdTe is noisier than that one formed on silicon. This, along with the additional junction 48, is likely to increase noise current and thereby reduce the efficiency of the infrared device. Furthermore, the top regions 51 of the detectors involve passivation of narrow band gap HgCdTe material and hence do not solve the objective of p-n junctions buried in wider band gap HgCdTe material 33.

Furthermore, in both Methods A and B, the photo-generated carriers in the vicinity of the p-n junction are likely to reach the infrared receiving surface and recombine resulting in loss of signal, thereby decreasing the sensitivity of the device. This is true for region 51 in Method C too. Furthermore, in all the three Methods A to C, the signal processing circuits 37 to 39 are formed in HgCdTe instead of silicon. The density and performance of the state-of-the-art integrated circuits (IC) involving millions of transistors formed on silicon substrate are much higher than that on HgCdTe substrate and the silicon IC technology is far more advanced and reliable.

The increased demands on the performance of silicon semiconductor devices and microcircuits have required the development of improved processing techniques. The current invention is to produce high efficiency monolithic infrared devices by integrating advancements in silicon-based ROIC and HgCdTe-based infrared detector technologies. The current invention also eliminates the low yield indium bump and hybridization processes, thus significantly reducing the cost of the currently available infrared systems. A key advance in the modern solid-state technology is clean processing in order to prevent the contamination of sensitive surfaces so that the stability and reproducibility of device characteristics are improved.

Traditionally, the Si wafers were cleaned using wet chemical etching processes, such as the RCA process¹ and the Shiraki processes² and a thermal cleaning in vacuum. For the Si wafers to be ready for epitaxial growth they have to undergo a contaminant removal step as well as a surface passivation step. The contaminant removal step assures that the Si surface is clean and free of foreign elements (contaminants). ¹^{¹} W. Kern and D. A. Puotinen, Cleaning solution based on hydrogen peroxide for use in silicon semiconductor technology, RCA Rev. 31, 187 (1970) ² Japanese Patent Application No. Sho. 63-46765

Surface contaminants can be classified as molecular, ionic and atomic. Molecular contaminants are typically carbo-hydroxides and carbo-hydrides originating in the mechanical operations performed during the fabrication and handling of wafers. Organic solvent residues, grease or greasy films from containers are such molecular impurities held usually by weak electrostatic forces. Ionic contaminants are typically present after chemical etching, and can be physisorbed or chemisorbed onto the surface. Alkali ions are particularly harmful for epitaxial growth since they are known to give rise to different crystal defects. Atomic contaminants include metals such as gold, silver and copper. Atomic impurities, especially the heavy ions, have a detrimental effect on the overall performance of the devices.

Once the contaminants are removed from the wafers, the bare Si atoms of the surface are highly reactive. Atoms lying on the surface have electrons that do not participate in the bonding with the bulk atoms, creating so-called dangling bonds. These dangling bonds represent unsaturated conditions with a high potential energy. They tend to grab and form bonds with any available atoms and therefore re-contaminate the surface.

In order to prevent the contamination of these surfaces during further processing and/or handling (like the loading into the MBE chamber) a passivation step is necessary. This step is to passivate the ROIC surface on which the II-VI materials are to be grown subsequently and needs to be distinguished from the passivation of infrared devices fabricated on the II-VI layers by CdTe discussed later in this invention. This particular passivation step consists of a controlled deposition of a thin layer of oxide that can be removed by thermal heating to re-reveal the dangling bonds of the surface Si atoms. More particularly, the oxide layer is thermally desorbed at temperatures above 850° C. in MBE growth chamber, thereby exposing a clean Si surface suitable for epitaxial growth. Importantly, the conventional approach requires thermal treatment of the Si wafer at a temperature above 850° C. to remove the passivation layer. The performance of the ROIC will severely degrade if this high temperature cleaning process is adopted for the current invention of monolithic infrared detectors. One of the key aspects of the current invention is to prepare the ROIC surface at temperatures not exceeding 500° C., discussed as follows.

Moreover, the crystal quality of HgCdTe grown on conventional CdZnTe bulk substrates or CdTe thin films is detrimentally impacted by the substrate's surface quality. More particularly, the cleaning process results in an uneven surface due to the different etching (reaction) times of the various constituents (such as Cd vs. Te, or Cd vs. Zn). The HgCdTe crystal quality is affected by the defects that are formed at the interface during the nucleation. Moreover the contamination that is created by exposing the substrates to the environment is not entirely removed by the cleaning process. The presence of foreign atoms on the substrate creates nucleation centers for defects within the HgCdTe layers.

Read-Out Integrated Circuits (ROIC) are prone to failure at high temperatures. Consequently, applications requiring an opto-electronic device structure to be grown on an ROIC require that the entire process, be carried out at temperatures below the maximum sustainable temperature of ROIC, which is about 500° C. Conventional methods for preparing Si wafers are not acceptable because they require a thermal treatment at or above 850° C.

Accordingly, a first object of the present invention is to provide a new two-step process for cleaning a silicon wafer.

Another aspect of the invention relates to an improved method for removing the oxide passivation layer created on the ROIC surface before the growth of II-VI layers commences. More particularly, an object of the present invention is to provide a method for removing a passivation layer at a temperature below the maximum sustainable temperature of read out integrated circuits (500° C).

Yet another object of the present invention is to provide a high sensitivity monolithic infrared photon detector including a read-out integrated circuit fabricated on silicon and high quality multi-layer HgCdTe layers grown directly on the silicon/silicon-ROIC.

Another object of the present invention is to provide a monolithic interconnect between the detector contacts and the ROIC input gates involving a height difference of over 15 microns.

### SUMMARY OF THE PRESENT INVENTION

An infrared sensing device is provided which includes at least one infrared detector containing at least one planar photovoltaic diode fabricated on a mesa-shaped II-VI semiconductor multi-layer structure produced by molecular beam epitaxy technique on a readout integrated circuit, which is pre-fabricated on a special silicon substrate. At least one infrared detecting cell is formed in the mesa, with a conductive interconnect layer connecting the detection cell to the readout integrated circuit.

According to one aspect of the invention, the readout circuit (ROIC) that is needed for processing the signal generated by an infrared device is custom designed and fabricated in a standard semiconductor foundry. In the prior art such ROICs are fabricated on (100) oriented silicon wafer in such a way that the ROIC could be joined to the infrared device containing plurality of detectors by indium columns formed on each detector. This process of joining the infrared device and ROIC device is called hybridization. The yield in these devices is poor due to the difference in the thermal expansion coefficients of the ROIC and infrared device at the operating temperature of 77K and high-risk hybridization process. In this aspect of the invention, to enable defect-free II-VI semiconductors on silicon, the authors found that the ROIC needs to be fabricated on silicon substrates with one degree or the like tilted from the (100) crystal direction. This ensures twin-free growth of II-VI HgCdTe layers. Secondly, to preserve the circuits in the ROIC, a window free of any underlying circuits is provided for the subsequent growth of II-VI layers. To fabricate a plurality of infrared detectors connected to the ROIC, the signal input gates covered with aluminum metal are provided in at least one row adjacent to the growth window. A second design to incorporate two rows of infrared detectors, the ROIC input gates are arranged in two rows on either side of the growth window.

According to another aspect of the invention, a procedure to prepare the ROIC surface at or below 500° C. is provided. The authors have found that this is the maximum temperature to which the ROIC could be subjected during the II-VI material growth. In the prior art, to grow II-VI material by MBE, the substrates need to be cleaned at or above 850° C.

According to another aspect of this invention, the authors present the procedure to grow a multi-layer HgCdTe structure on the ROIC prepared according to the previous aspect of the invention. Due to the 19.3% lattice mismatch between the silicon and II-VI materials, it was previously thought that II-VI layers cannot be grown on silicon. By employing the surface preparation outlined above and growing a CdTe buffer layer, the authors have achieved single crystalline growth (the crystallinity is confirmed by the streaky RHEED (reflection high energy electron diffraction) pattern observed during the MBE growth) of at least one HgCdTe layer on the ROIC pre-fabricated on one-degree tilted (100) silicon substrates.

According to another aspect of the invention, the authors fabricate a plurality of mesa structures containing at least one photovoltaic infrared detector that includes at least two layers of Group II-VI semiconductor material having different band gaps. Each infrared detecting cell is electronically connected to the corresponding signal input cell in the ROIC. The wider band gap layer significantly reduces the surface passivation-related leakage currents in the infrared detector.

According to yet another aspect of the invention, the signal output from each detector is conductively connected to the signal input cell of ROIC. Since the detector output and the ROIC input cells are located in two different planes with at least 15 microns height difference, the authors fabricate a mesa structure at the edges of the growth window. Note that the photovoltaic junctions are planar junctions located on the top surface of one long mesa (of nearly the dimensions of the growth window). The mesa structure at the edges of the growth window is constructed by a special etching in bromine-methanol solution. Each detector output cell is then connected to the plurality of ROIC signal input gates by individual metal electrodes running down the low angle slope of the mesa despite the large height difference between these two planes. The mesa has at least one sloped side on which a conductive trace connecting the detector output and the input of the readout integrated circuit is formed. Also, the detector common cell is connected to the ROIC common cell in a similar way.

### BRIEF DESCRIPTION OF THE DRAWINGS

FIG. 1 shows the unit cell for a cubic lattice and several crystal directions;

FIG. 2 is a schematic diagram of silicon (211) surface;

FIG. 3 is a schematic diagram of silicon (001) surface;

FIG. 4 shows a tilted (001) silicon surface;

FIG. 5a is a physical diagram and 5b is the energy band diagram of a p-n junction;

FIG. 6 is the silicon (001) surface passivated with Hydrogen atoms;

FIG. 7 shows the silicon (001) surface of FIG. 6 after heating under ultra high vacuum (UHV); passivation is removed, the dangling bonds are exposed

FIG. 8 shows an over-etched (001) surface and the effect of over-etching the (111) facets;

FIG. 9 describes the prior art process for growth of MCT (FIGS. 9a and 9b) versus the newly proposed process (FIG. 9c);

FIG. 10 shows the temperature profile for growth of MCT when using a single chamber versus using a plurality of MBE systems;

FIG. 11 is a top view showing the infrared devices monolithically connected to the input gates of a readout circuit, according to one of the two design formats of the current invention.

FIG. 12 is a cross-sectional view of a monolithic infrared device shown in FIG. 11;

FIG. 13 is a top view showing two linear arrays of infrared devices monolithically connected to the input gates of the custom designed readout circuit in accordance with the another embodiment of the present invention;

FIG. 14 is a cross-sectional view taken substantially along lines 110-110 of the monolithic infrared device shown in FIG. 13;

FIGS. 15(A) to 15(L) are cross sectional views corresponding to FIG. 14 showing respective steps in the process for producing the prior art infrared imaging device;

FIG. 16 is a cross-sectional view showing a second prior art infrared imaging device (Method-A);

FIG. 17 is a cross-sectional view showing a second prior art infrared imaging device (Method-B); and

FIG. 18 is a cross-sectional view showing a third prior art infrared imaging device (Method-C).

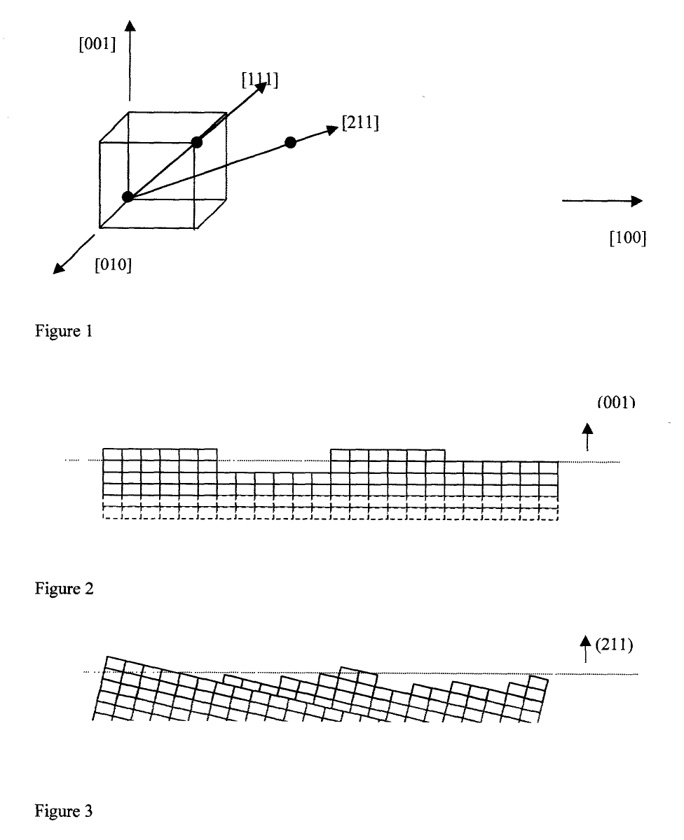

### DETAILED DESCRIPTION OF THE INVENTION

A technology for producing a plurality of infrared sensing elements in a monolithic array format is provided. Each element has a multi-layer structure of mercury cadmium telluride (HgCdTe), a group II-VI semiconductor grown by MBE on a pre-fabricated silicon-ROIC. The infrared sensing devices of the present invention are individually and monolithically connected to the signal input cells of a readout electronic circuit (ROIC). In other words, both the infrared sensing elements and the read-out electronics are fabricated on a common silicon substrate. The monolithic connection of the present invention eliminates the need for conventional columnar indium metal electrodes and the low-yield hybridization process (needed to interconnect the detector chip and the ROIC chip) by the direct growth of the complex HgCdTe structure on pre-fabricated read-out electronics on a common silicon substrate by Molecular Beam Epitaxy (MBE).

The present inventors have discovered that Silicon (Si) covered by a thin buffer layer film of, for example, CdTe (cadmium telluride) is a viable alternative substrate to bulk CdZnTe. Specifically, they have invented that a readout circuit (ROIC) pre-fabricated on silicon can be used as substrate for CdTe buffer and subsequently HgCdTe detector layers growth by MBE resulting in ‘monolithic infrared detectors’. The authors have found that the maximum sustainable temperature of the ROIC during cleaning and the growth is 500° C. Consequently, they have developed process cycles to: “pre-growth cleaning of the ROIC, passivate with Hydrogen, remove passivation under safe conditions, CdTe buffer-growth and at least one HgCdTe layer”.

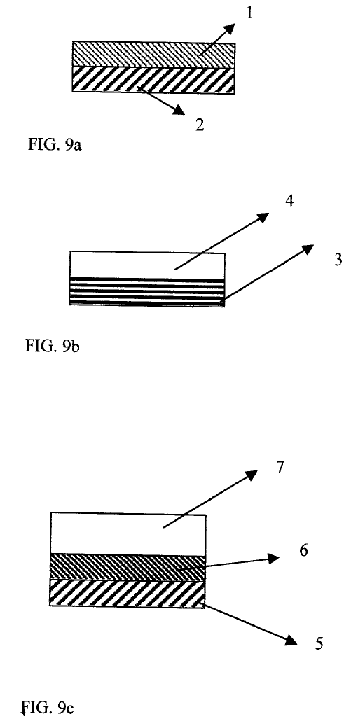

Current growth techniques of HgCdTe on Si (FIG. 9a 2) use two separate MBE systems, one that will allow the growth of CdTe thin films on silicon (FIG. 9a 1) that will become a substrate for growth in the second chamber (FIG. 9b 3). The newly formed substrate is suited for growth after undergoing a typical substrate cleaning procedure. HgCdTe (FIG. 9b 4) is then grown in the second system.

One aspect of our invention offers the alternative to use one chamber only, capable of carrying the necessary charge sources. The growth will then be involving a buffer layer (FIG. 9c 6) grown on Si (FIG. 9c 5), followed by the growth of HgCdTe (FIG. 9c 7). The growth schematics for the two processes are shown in FIGS. 10a and 10b. FIG. 10a shows the substrate temperature profile for the growth using one MBE system versus (FIG. 10b) using two separate systems.

After the aforementioned clean-growth processes, the authors developed infrared devices monolithically connected to the underlying ROIC. The current invention couples the high performance of silicon signal processing readout circuits (Si-ROIC) with HgCdTe-based infrared devices.

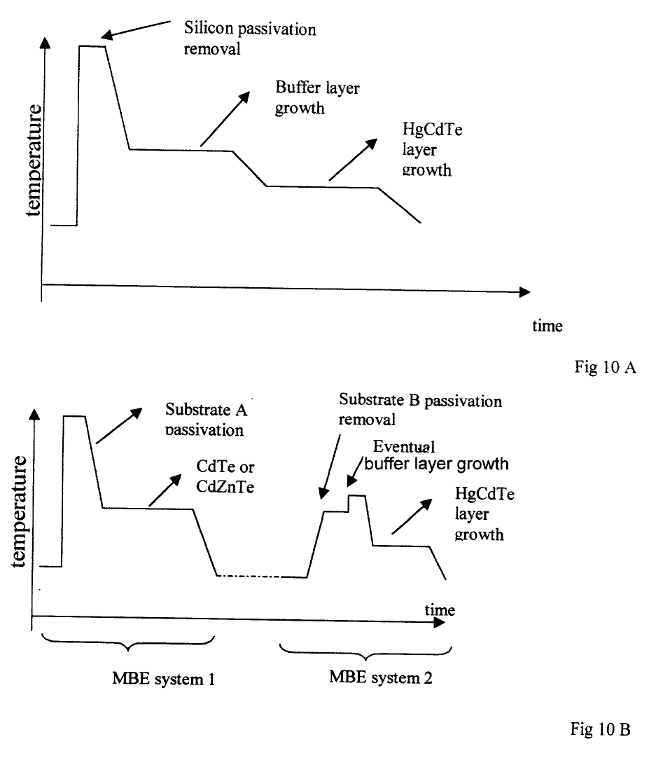

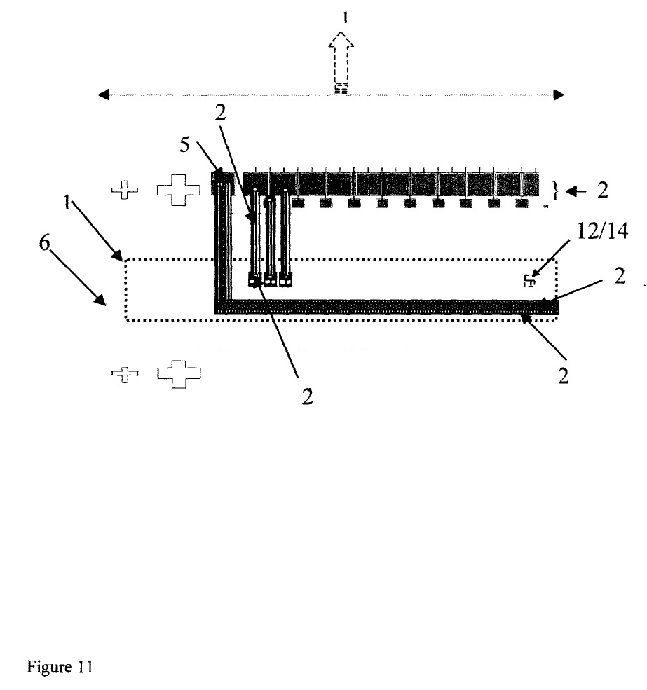

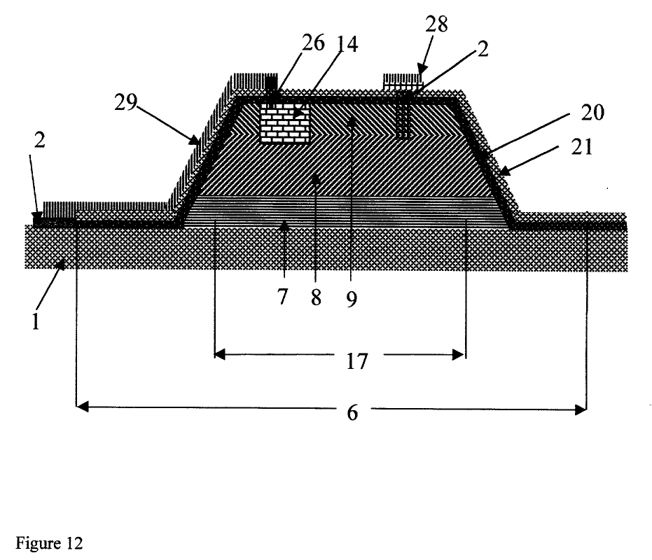

Two different designs for the monolithic infrared detector arrays are illustrated here. In the first design format (FIG. 11 and 12), a linear array of infrared detectors containing planar photovoltaic junctions are fabricated on a mesa formed in the II-VI material that grows between the detector output cells and the ROIC input cells. Each detector output is then monolithically connected to the ROIC input cells by conducting lines flowing down the mesa slope.

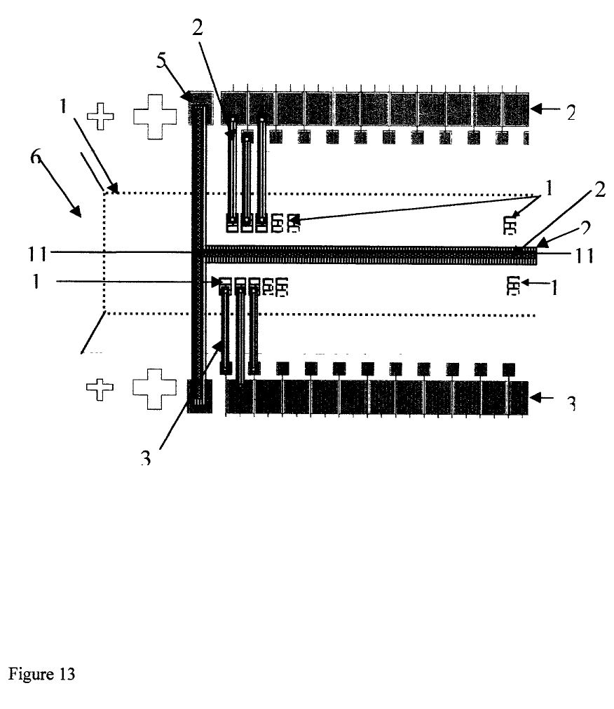

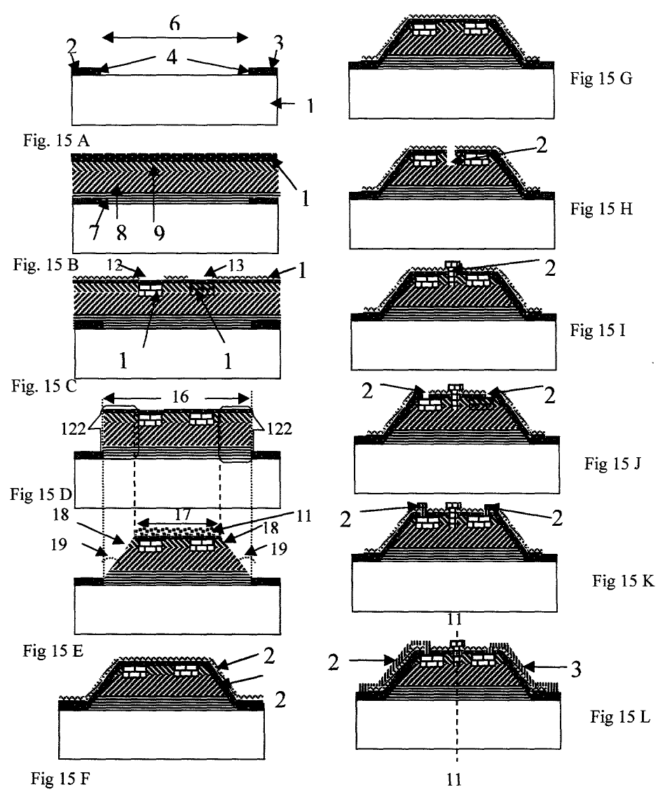

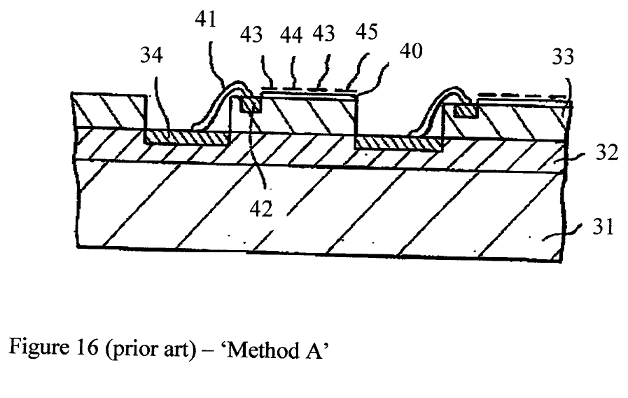

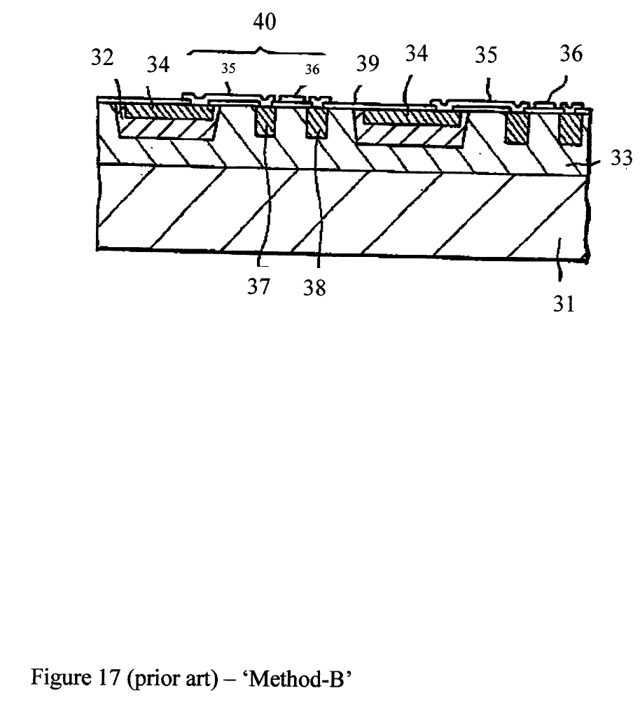

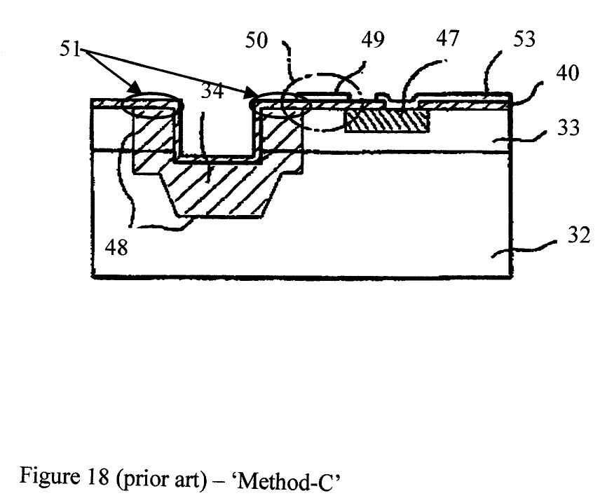

The output of each detector (14 in FIG. 11) is monolithically interconnected 29 to a corresponding signal input gate defined by the row of metal pads 2 (FIG. 11) and the detector common 23 is fabricated as a long strip along the length of the ROIC 1 and is monolithically interconnected 28 to the ROIC common contact pad 5. In the second design format (FIGS. 13 to 15) a mirror image of the previous design is added to the circuit in the y-direction (vertical in the page) giving rise to simultaneously producing two similar linear arrays, which if needed could be separated by cutting along the center line 110-110 (FIG. 13). The entire process of fabrication of devices in these two formats is essentially the same and illustrated in FIG. 15, for the second design format device.

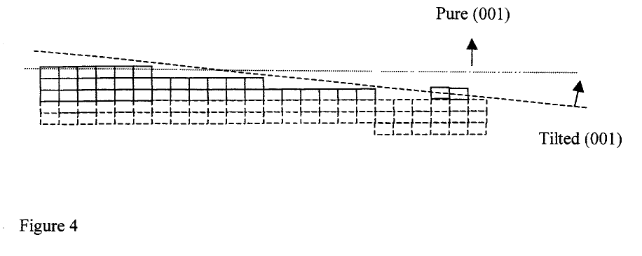

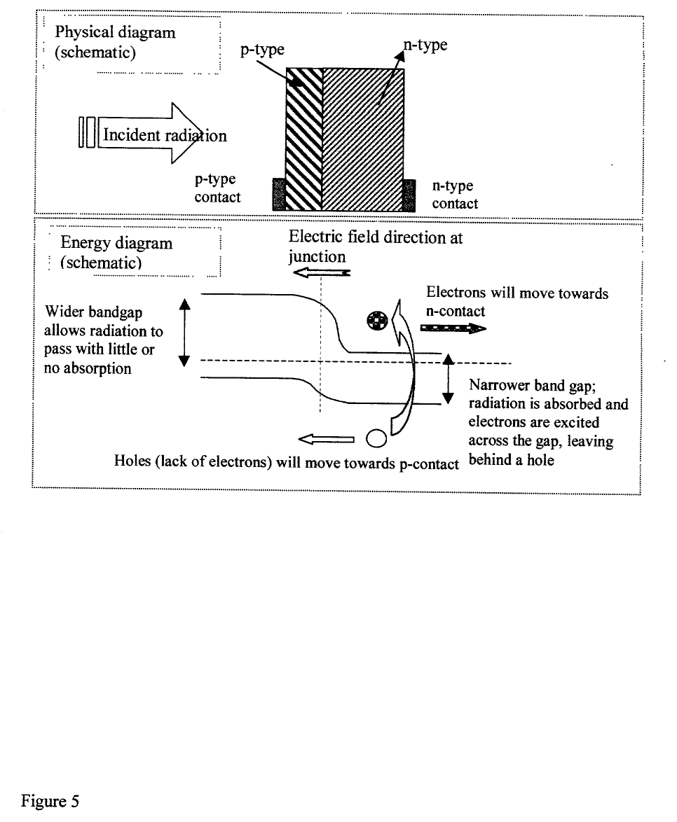

The enormous lattice mismatch between the silicon (substrate for ROIC) and HgCdTe layers (for infrared detection) is overcome by the growth of a CdTe buffer layer. The growth of CdTe(111)B (where B represents the polarity of the molecular arrangement, i.e., Te terminated surfaces) can be performed successfully on Si(001) tilted around 1° off axis. The tilt of the surface orientation enhances the correlation between seeds and suppresses twin crystal formation, leading to a single crystal film. A schematic diagram of such a surface is shown in FIG. 4.

For a tilted (001) surface the morphology shows terraces and additional steps spaced out to accommodate the surface tilt. The tilted surface induces a larger number of steps on the surface, and these steps are beneficial for the growth of twin-free single crystal material.

The silicon (Si) substrate, which is rather inexpensive, offers a rugged, stable mechanical support for the entire structure. Moreover, the Si substrate can carry an additional microelectronic device enabling further integration with the devices to be fabricated onto MCT. More particularly, according to the present invention MCT detectors are monolithically integrated with Si Read-Out Integrated Circuits (ROIC), providing substantial benefits over conventional techniques in which ROIC are hybridized onto MCT detectors using Indium bumps.

Similar results may also be achieved by combinations of buffer layers other than CdZnTe and other II-VI semiconductor layers for infrared absorption. The p-n junctions in a device formed according to the present invention are planar and are totally buried under a wide band gap HgCdTe layer achieving very high dynamic impedance and sensitivity.

An aspect of the present invention relates to a procedure to clean ROIC-Si(001) in preparation for epitaxial growth of semiconductor films by MBE. The semiconductor films are grown on a vicinal or off-angle silicon wafer, at a temperature below the maximum sustainable ROIC temperature of 500° C.

Si-ROICs are commercially suitable for hybridization. A modified ROIC according to the present invention includes a circuit fabricated on a silicon wafer having a tilted orientation and having a window uncovered by previously fabricated circuits, that will be used for growth of detector material is described herein. Growth of II-VI semiconductor material on Silicon wafers with built-in ROICs can be performed on various Si orientations, like (211), (111), nominal surfaces or off-axis.

Si(001) wafers have been considered the most widely used semiconductor material for fabrication of various advanced electronic devices and as substrates for the growth of many homoepitaxial or heteroepitaxial layers, such as Si/Si, SiGe/Si, GaAs/Si, ZnSe/Si and CdTe/Si. For all these epitaxial structures, a clean Si substrate has to be prepared prior to the onset of the epitaxial growth. A large number of contaminants present on the Si surface can prevent the growth of single crystalline material, while a reduced number of contaminants results in the growth of an epilayer with a commensurate level of defects. Ideally, all contaminants are removed in order to obtain reliable and reproducible results.

Prior to applying the methods described in the current innovation, the surface of the Si(001) wafer must be cleaned and passivated. More particularly, the wafer may be cleaned using a conventional wet chemical method or the like in order to obtain an atomically clean surface.

Alternatively, the wafer may be cleaned using an oven containing a source of ozone, such as a Mercury lamp. The ozone generated in the oven will react with the wafer contaminants and reaction products will be removed. However, the use of low temperature cleaning process is preferred, because the components in the ROIC degrade if subjected to temperatures >500° C.

To prevent recontamination, it is necessary to cover the freshly cleaned surface with a thin oxide to passivate any dangling bonds on the cleaned surface. Moreover, this oxide layer needs to be removed in-situ in the MBE chamber before the CdTe buffer layer growth starts.

A first aspect of the present invention relates to a two-step etching process for removing the oxide layer selectively from the growth window 6 shown in FIGS. 11, 13 and FIG. 15a. First, the wafer is wet etched in a diluted solution of HF:H₂O (2-10%) for 50 to 80 seconds. The water used in the wet etch solution should be deionized water with above 18 megaohms resistivity. The first etching step must be sufficient to effectively remove the oxide layer previously formed.

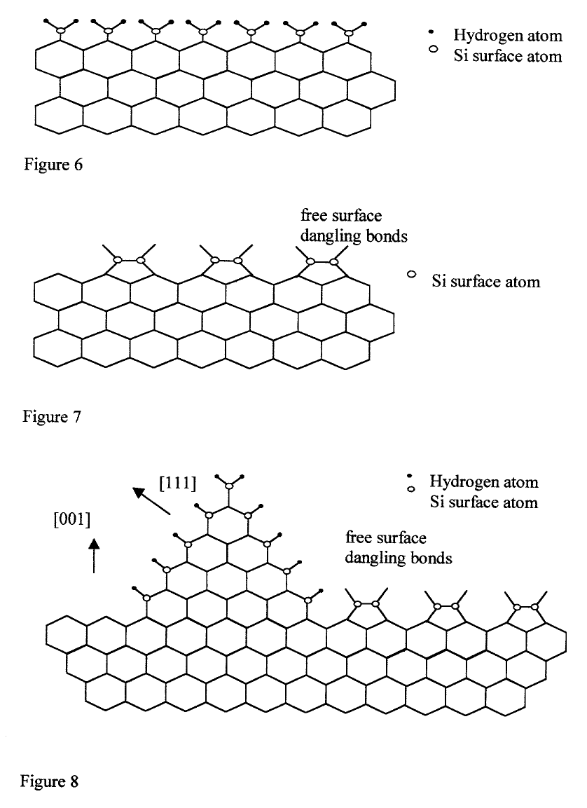

After the first etching in HF solution, the wafer is slowly pulled out of the solution and immediately submerged into concentrated NH₄F (20%-40%). The period of time during which the ammonium fluoride etch is performed is critical. A short exposure leaves an uncovered silicon surface, sensitive to future contamination, and most of the hydrogen passivation/termination is in the form of mono- and trihydrides. A long etching time in NH₄F produces rough surfaces with (111) facets covered by monohydrides. This second wet etch will yield a dyhdride terminated, smooth Si(001) surface for etching periods of 30+/−10 seconds. The dyhdride terminations provide a passivation layer. (FIG. 6)

Etching of the ROIC 1 with open windows 6 that expose the silicon can be performed either by dipping the entire wafer into chemicals or by dispensing onto the wafer certain amounts of chemicals while it is spinning. The growth window is rectangular defined along the length of the ROIC and covers the area between the two rows of ROIC pads 2,3 as shown in FIGS. 11 to 15. This window consists of clean silicon surface after the procedure described above is performed.

To produce the monolithic infrared device, two embodiments consisting of two different design formats are presented in this invention. The first design shown in FIGS. 11 and 12 consists of a linear array of planar photovoltaic infrared detectors fabricated on a mesa formed in the II-VI material structure in window 6. The detector outputs 26 and the detector common 23 are monolithically connected (29 and 28) to the corresponding input gates of the ROIC (FIG. 11). The signal input gates 2 of the ROIC are arranged in a row on the topside of the growth window as illustrated in FIG. 11. The detector common contact 23 is defined as a long strip parallel to the row of detectors (14 in FIG. 11) on the mesa and later conductively connected 28 to the ROIC common 5.

The second design format consists of two rows of ROIC signal input gates arranged on either side (top and bottom) of the growth window as illustrated in FIG. 13. In this format, the plurality of detectors is fabricated in two adjacent rows (with the detector common running at the center between the two rows of detectors FIG. 13). The output of one row of detectors 26 are connected to the top row of signal input gates 2 of the ROIC 1, while that of the second row of detectors 27 are connected to the corresponding input gates in the bottom row 3 (illustrated in FIG. 13). As before, the detector common 23 is conductively connected 28 to the ROIC common 5. The rest of the details and procedure for the growth of infrared detecting layers and fabrication of detectors are same in both embodiments.

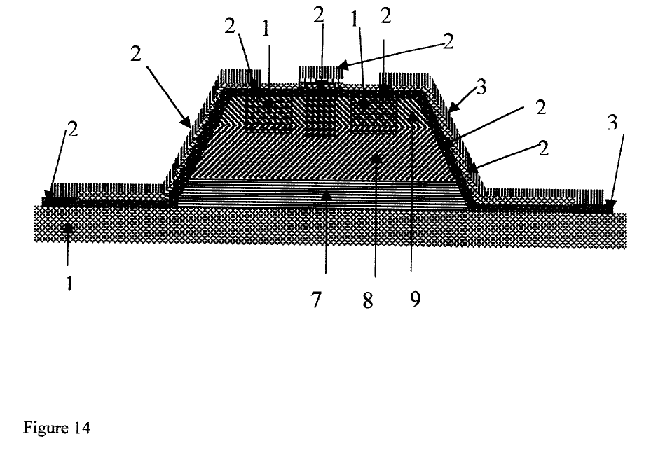

The step-by-step procedures common to both design formats for the growth and device fabrication is illustrated in FIG. 15 as an example, for the second design format. The FIGS. 11 and 13 show a part of the custom designed ROIC in the two formats. On the top and bottom side of these figures, the rest of the signal processing electronics are arranged (not shown since they do not concern the current invention). Also these figures show only a few of the detectors of the total 256 detectors in one row (the first design, FIG. 11) or 512 detectors in two rows (256 in each row, the second design FIG. 13) connected to the ROIC. The corresponding cross sectional views of one of the detector element are shown in FIGS. 12 and 14 respectively for the two design formats, respectively.

The entire process of monolithic infrared detector array fabrication involves three major steps:

1. The design and the subsequent fabrication of the ROIC in a foundry. Usually, the custom-designed ROIC is encapsulated with a protective silicon nitride or silicon dioxide layer at the end of the ROIC fabrication.

2. The growth of multi-layer CdTe/HgCdTe structure selectively in a window 6 on the ROIC 1. A window 6 where the encapsulant layer is removed and the silicon surface free of underlying circuits is prepared before the growth of CdTe/HgCdTe structure. Though the CdTe/HgCdTe structure grows on the entire ROIC, only that portion that lies within this window is single crystalline material suitable for the subsequent detector fabrication.

3. The fabrication of plurality of infrared detectors conductively connecting each detector signal output to the corresponding input gates in the ROIC. The detector common 23 is connected to the ROIC common contact 5 in a similar way, thus completing the monolithic infrared detector array. Also, this invention describes two design formats for the monolithic infrared detector array as discussed earlier and describes a method to achieve monolithic interconnects despite the large height difference between the two planes consisting of the detector outputs and the ROIC inputs.

Turning to the growth of infrared material on ROIC and detector fabrication, the first step is to open a window free of the encapsulant layer discussed earlier in the ROIC 1. As shown in FIG. 15(a), before the HgCdTe is grown on the Si-ROIC 1, a buffer layer 7 of single crystalline CdTe is formed within a window 6 in the encapsulant layer 4 on the ROIC 1. Specifically, the ROIC 1 is loaded into an ultra high vacuum system chamber, and the growth window 6 is stripped of the passivation layer to expose the clean silicon surface and a buffer layer 7 is grown across the ROIC substrate 1 according to the Si crystalline orientation. The buffer layer can be any II-VI compound or materials of similar structure (Arsenic, Phosphorous, Germanium, Antimony) or compounds selected from the group (CdTe, ZnTe, HgTe, HgCdTe, ZnSe, ZnSSe, and CdZnTe).

Once, the substrate is thermally cleaned inside the chamber and a proper elemental Si surface (in the growth window 6) is observed by reflection high-energy electron diffraction (RHEED), the CdTe growth is initiated.

More particularly, after the removal of the passivation 4 (FIG. 15a) from the growth window 6, the substrate is cooled under Arsenic flux from 500° C. to 400° C., followed by a cooling under CdTe flux from 400° C. to 350° C. Next, the substrate is cooled down to 210° C. and CdTe is deposited at this temperature for about 2 minutes. The substrate is then heated to about 310° C. under Te flux and from 320° C. to 350° C. under Te and CdTe fluxes. The substrate is kept at 350° C. for 10 minutes under CdTe and Te fluxes. Next, the substrate is cooled to about 310° C. under Te flux. At this temperature additional 4-8 microns of CdTe are grown with CdTe flux that assures a growth rate of about 2 Å/second.

After this process, the sample is cooled to the HgCdTe nucleation temperature of about 180° C. and allowed to stabilize for about an hour under no material flux. The HgCdTe growth process is then initiated. First the grown CdTe surface is exposed to the Hg flux. The flux is adjusted such that the chamber pressure is around 2.0×10⁻⁵ Torr. Next, a Te flux is provide for about 10 seconds followed by a subsequent exposure to CdTe. The Te and CdTe fluxes are adjusted so that their ratio provides the growth of HgCdTe with desired composition. During the growth the surface is always exposed to Hg, Te and CdTe fluxes. The substrate temperature is ramped down during the growth of HgCdTe to compensate for the heat absorption into HgCdTe layer, as it grows. The HgCdTe growth process takes approximately 4 hours, and the entire growth time, from loading to unloading, takes about 20 hours. The result is shown in FIG. 15b.

In FIG. 15(b), once the buffer layer 7 is grown, the growth of HgCdTe commences. It should be noted that, depending on the buffer material used, a waiting period may be necessary prior to MCT growth. The waiting period being defined by the difference between the growth temperature of the buffer and the growth temperature of the HgCdTe layer, and by the system ability to adjust to the new temperature setting.

During the waiting period the buffer layer may be exposed to specific fluxes (like Tellurium, Mercury, others) in order to prevent any material or specific atomic species from desorbing.

The details of the device and the fabrication process are described as follows. FIG. 11 is a top view of a monolithic ROIC/HgCdTe detector cell array according to the first of the two designs presented in this invention. Si-ROICs are commercially suitable for hybridization. A modified ROIC according to the present invention includes a circuit fabricated on a silicon wafer having a tilted orientation and having a window 6 uncovered previously to the II-VI material growth on the ROIC 1. Growth of II-VI semiconductor material on Silicon wafers with built-in ROICs can be performed on various Si orientations, like (211), (111), nominal surfaces or off-axis. At the end of the manufacturing process of the ROIC, the entire ROIC 1 is covered with silicon nitride or silicon dioxide encapsulant (4 in FIG. 15a, shown partially after selectively etching it from the growth window). A window 6 is etched in the custom designed ROIC 1 in a region that is free of any underlying circuits (see FIGS. 11 to 15). A part of the ROIC relevant for the growth of HgCdTe material and subsequent device fabrication is shown here. On either end (top and bottom), rest of the readout circuits including the shift registers for the signal processing is distributed (not shown here).

FIG. 12 is a cross-sectional view of FIG. 11 taken substantially along line 110-110 of FIG. 13.

In the first design, the ROIC 1 is provided with a plurality of signal input gates in a row 2, each covered with aluminum metal. The size of the alternate plurality of pads 2 is relatively large, 75×100 microns to facilitate bonding to a test board (not illustrated) and statistical testing of the infrared detectors. Referring to FIG. 15(a), a window 6, clear of any underlying circuit is provided for the subsequent growth of infrared sensitive material. A protective layer of silicon nitride (not shown) covers the entire ROIC surface 1 except the bonding pads 2,3 (FIG. 11, 13 corresponding to the two designs) as discussed earlier. Prior to the HgCdTe growth, the protective layer is selectively removed in the growth window 6 by performing the standard photolithography technique. The wafer is then loaded into an ultrahigh vacuum MBE chamber. The surface preparation and growth of CdTe buffer 7, HgCdTe layers 8,9 and the CdTe cap layer 10 structure are carried out in accordance with the previously described procedure.

A first buffer layer 7 approximately 5 to 8 microns thick of CdTe is disposed on the ROIC 1 by MBE to reduce the lattice mismatch between silicon and the subsequent layers of HgCdTe.

A first layer 8 of HgCdTe, about 10 microns thick, with narrow band gap, is deposited by MBE on the buffer layer 7. The band gap of the HgCdTe 8 is selected in accordance with the desired cutoff wavelength of the detector.

A second HgCdTe layer 9 with wider band gap (compared to the previous HgCdTe layer 8) and about 1 micron thick is then deposited, followed by the deposition of a thin CdTe layer 10 for protection of the entire structure.

Both the HgCdTe layers 8 and 9 are doped with indium during the growth to make electron as the dominant current carrier (n-type). The entire sample is then coated with a 5 micron thick photoresist 11. A plurality of windows 12 and 13 (FIG. 15c) (in the case of the first design format only the windows 12 are present, ref to FIG. 11) are then selectively opened in this photoresist 11 by photolithography, a common technique known to everyone familiar with this art.

The plurality of p-n junctions(14 in FIG. 11 for the first design and 14,15 in FIG. 13 for the second design) is then fabricated by implementing arsenic atoms through these windows 12 (and 13 in the case of second design) selectively by ion implantation technique. Ion implantation is one of the standard techniques to change the polarity of the electrical conduction in selected regions in a semiconductor. After opening windows in the 5 micron thick photoresist 11, arsenic ions are implanted with 350 keV energy and a dose of 1×10¹⁴ cm⁻².

Due to the high initial energy (350 keV), arsenic travels through the entire thickness of HgCdTe layer 9 through the windows 12 (and 13) and forms a p-n junction in the n-type HgCdTe layer 8 once the arsenic atoms (a p-type dopant in HgCdTe) are electrically activated as described below. Outside of window 12 (and 13) the photoresist 11 prevents the implanted arsenic entering in to the HgCdTe layers thus achieving selectivity. The implanted arsenic atoms by themselves are not electrically active.

A post-implant annealing is performed to activate these arsenic atoms to change the conductivity in regions 14,15 to p-type. The layered, selectively implanted ROIC 1 is then annealed in an ampoule containing mercury overpressure to activate the arsenic. The ampoule contains two compartments with a constriction in between. The sample is placed in the top compartment while a tiny droplet of mercury is placed in the bottom. Due to the high vapor pressure of mercury, the top compartment is under mercury over pressure. A tiny droplet of mercury provides enough overpressure to avoid any outdiffusion of mercury from the sample surface.

The mercury over pressure is necessary to avoid the creation of vacancies in the multi-layer HgCdTe structure by outdiffusion of mercury atoms. The annealing is done in three steps: 425° C., 10 minutes; 300° C., 12 hours; 235° C., 12 hours. This annealing gives rise to about 10¹⁷/cm⁻³ hole carriers in the arsenic doped regions 14,15 and about 10¹⁵/cm⁻³ electrons in the indium doped n-type HgCdTe layers 8 and 9. The plurality of junctions 14,15 is now capable of collecting the electron hole pairs (signal) generated by the incident infrared radiation by the built-in potential difference at the junction due to opposite conducting polarity on either side of the junction.

After the annealing, the masking photoresist layer 11 is removed in acetone and the sample is thoroughly cleaned in methanol, followed by DI water. In the next step, the grown infrared material structure in the window 16 (FIG. 15d) is selectively protected by 5 micron thick photoresist while the material from rest of the areas on ROIC 1 is removed. After protecting the wanted areas 16, the removal of the material from other areas could be accomplished using standard dry etching techniques or by chemical etching in 2% bromine in hydrobromic acid in about 3 to 5 minutes. This leaves the infrared sensitive HgCdTe material structure in the original growth window 6 but removes the material from unwanted areas and exposes the ROIC contact pads 2,3 as shown in FIG. 15d.

In the next step, the material on windows 17 that is dimensionally within the windows 16 is protected as before, leaving the rest of the areas 122 open. Then the entire sample is dipped in 4% bromine in hydrobromic acid solution for a few seconds. This produces a mesa structure (FIG. 15e) with a 40 to 50 degree angle 19 between slope 18 (mesa side walls) and the surface of ROIC (horizontal plane).

The formation of the slope in the mesa structure can be better visualized by comparing FIG. 15d and 15e. The reason for the formation of slope is as follows. Due to the residence time of the etching chemical and the high concentration, the top layers in the strip of material structure that lies between the windows 16 and 17 gets etched first. As the etching proceeds to remove the bottom layers, lateral etching occurs in the region where the top layer once was resulting in a sloped side 18 (FIG. 15e).

The photoresist 11 is then washed off in acetone. The entire sample is then dipped in 0.05% bromine in methanol solution for about 20 seconds. This removes the CdTe cap layer 10 from the top surface of the mesa. A thin CdTe layer 20 (1000 angstrom thickness) followed by 2000-angstrom thickness of ZnS 21 are then deposited on the surface of the sample for passivating and protecting it. The cross sectional view of the device at this stage is shown in FIG. 15(f).

One of ordinary skill in the art will appreciate that standard methods like thermal or electron beam evaporation may be used in place of MBE to deposit these CdTe 20 and ZnS 21 layers. Note that the layer 20 and 21 also covers the ROIC contact metal pads 2 and 3. In the next step the CdTe 20 and ZnS 21 are removed from the ROIC contact metal pads selectively by protecting the entire mesa structures with photoresist by performing photolithography. The exposed CdTe 20 and ZnS 21 on the ROIC input metal pads are etched off typically in about 40 seconds by dipping successively in buffered hydrofluoric acid (20 sec) and buffered hydrochloric acid (20 sec) (FIG. 15g).

In the next step of photolithography, a window 22 is opened (FIG. 13h) in the protective photoresist and the ZnS 21, and CdTe 20 layers are removed selectively in this window 22, to facilitate contact metal deposition for detector common contact with the HgCdTe layer 8. Another step of photolithography is done to deposit indium metal 23 of thickness about 1000 angstrom selectively in window 22 by lift-off technique (FIG. 13i). Then contact windows 24, 25 for the p-regions 14 and 15 are selectively opened (FIG. 13j) and 1000 angstrom thick gold metal 26, 27 deposited in exactly the same way as the common contact was made in the previous step (FIG. 15k).

The last step in the device processing is to connect the signal output gates 26,27 from each detector to the signal input gates 2,3 of the ROIC and similarly the detector common 23 to ROIC common 5. This is a very critical step because the ROIC metal pads 2,3,5 and the detector contact metal pads 26,27,23 are located in two different planes involving a height difference of about 15 microns or more. The interconnecting metal lines 28,29,30 (FIGS. 11 to 14) will break due to the height difference if a slope to ensure good step coverage is not fabricated prior to the interconnecting metal deposition.

The invention is to fabricate the mesa structure with the side walls sloped by 40 to 50 degrees with respect to the ROIC surface plane, as described earlier in reference to FIGS. 15d and 15e. According to this aspect of the invention, a method is disclosed for overcoming this barrier problem associated with connecting the detector outputs 26,27 to ROIC input metal pads 2,3. The same applies to the conducting line connecting the ROIC common contact 5 and the detector common contact 23. The interconnecting lines are defined photolithographically and consists of 0.05 micron thick titanium followed by 0.1 micron thick gold. The present inventors have discovered a reliable, cost-effective method for connecting the detector output metal pad 26 (and 27) to ROIC input 2 (and 3) by fabricating a low angle 19 slope/ramp 18 in the HgCdTe material lying between the regions 16 and 17. The cross section of the final device (in the second design format is shown in FIG. 15L)

As described earlier, the multi-layer material 122 that grows between a detector cell area 17 and the ROIC area 16 (see FIG. 15(e)) is used to fabricate a low angle slope. Notably, selected portions of the mesa 17 are protected with photoresist, and the unprotected regions are etched in a bromine-hydrobromic (HBr) acid solution or the like. Preferably, 4% bromine in HBr acid is used. The etching is done typically for a few seconds.

Due to the fast etching characteristics of this solution and its isotropic etching characteristics, considerable undercutting (due to lateral etching in the top layers while the etching proceeds vertically in the bottom layers) is achieved in the material 122, giving rise to a low angle slope as described earlier. The fast etching characteristics leads to considerable lateral etching in the top layers while the bottom layers in the material 122 are being etched in the vertical direction leading to a sloped wall instead of a vertical wall (which will be the case if no lateral etching occurs in the top layers) in the mesa structure.

The interconnections 29,30 between the detector output gates 26,27 and the corresponding ROIC input gates 2,3 are fabricated by depositing a titanium-gold bi-metal layer by a conventional photolithographic lift-off technique. Similarly, the metal electrode 28 connects the detector common 23 and ROIC common 5. First a titanium layer of about 400 to 500 angstrom is deposited followed by about 1000 angstrom of gold in the same evaporation run without breaking the vacuum. This low angle slope, which can be on the order of 40 to 50 degrees with respect to normal (perpendicular to the ROIC surface), is critical in ensuring proper step coverage when metal is deposited between the detector output and the ROIC input. In the same fabrication step, a similar conductive, monolithic interconnect between the detector common 23 and the ROIC common contact 5 is also established (the cross sectional view is shown in FIG. 15k).

A method for simultaneously producing two linear arrays per die will be disclosed with reference to FIGS. 13 and 15. The fabrication details described above are same in this design too and hence described briefly as follows.

FIGS. 13 and 14 show the top view and the cross-sectional view, respectively, of an array of devices in accordance with the second embodiment. The process sequence to produce this cell array is shown in FIG. 15(a) to 15(k).

The protective layer 4 of silicon nitride or silicon dioxide layer is selectively removed from the growth window 6 by lithography as shown in FIG. 15(a). The ROIC wafer 1 is then inserted into the high vacuum chamber of a MBE system and the surface prepared at or below the maximum sustainable temperature of ROIC in the manner previously described.

The material structure involves a series of layers 7, 8, 9 and 10 as before.

A plurality of p-regions is selectively implanted as shown in FIG. 15(c). The difference between this embodiment (FIG. 13) of the invention and the previous one (FIG. 11) is that the design and fabrication incorporates two similar linear arrays of detectors monolithically connected to two rows of ROIC inputs 2,3 (FIG. 13) instead of only one row of detectors and input gates in the ROIC (the mirror image plane between the two designs is shown along the line 110-110 in FIG. 15k. This leads to significant cost saving and technical advantage in imaging applications. Preferably, the p-regions are formed by implanting arsenic with 1×10¹⁴ Cm⁻³ dose at 350 keV energy, followed by thermal annealing under mercury overpressure at 425° C. for 10 minutes, 300° C. for 12 hours and 235° C. for 12 hours, as described before with reference to the first design. However, other methods like in-situ doping, diffusion of dopants like arsenic, gold, etc will also yield the same desired results. The thermal annealing electrically activates the impurity species. This procedure also enables the formation of actual electrical junction in the HgCdTe layer 8 by the diffusion of arsenic atoms through the HgCdTe layer 9.

Next, the II-VI material lying on the ROIC contact pads 2,3 is etched away as shown in FIG. 15(d).

The material 122 between the regions 16 and 17 is then chemically etched to form a slope as shown in FIG. 15(e). The fabrication procedure for this slope and the monolithic metal interconnects are the same as previously described for the arrays shown in FIG. 11.

The thermal process used to activate the impurity species degrades the interface between the CdTe layer 10 and HgCdTe layer 9. Consequently, the previously grown CdTe cap layer 10 is removed by etching in 0.5% bromine in methanol for about 20 seconds and a fresh CdTe layer 20 and ZnS cap layer 21 are deposited (FIG. 15(f)).

In the next step of photolithography, the CdTe 20 and ZnS 21 from the ROIC contact pads 2,3 are etched (FIG. 15g), exactly as described before. A detector common contact window 22 is then opened by photolithography (and the CdTe 20 and ZnS 21 are removed to enable contact to HgCdTe layer 9 [FIG. 15(h)].

FIG. 15(i) shows the device after the deposition of indium metal for the detector common contact defined by another photolithography step. Similarly contact windows 24,25 to the two rows of p-HgCdTe regions 14,15 are opened by performing another lithography step and gold metal 26,27 of thickness 1000 angstrom deposited as shown in FIGS. 15(j) and 15(k).

FIG. 15(L) shows the final step of fabricating a monolithic metal interconnect 15 by depositing titanium and gold bi-layer. Either lift-off or selective metal etching could be done to accomplish this step, although liftoff is the preferred mode for this step.

While various embodiments of the present invention have been shown and described, it should be understood that other modifications, substitutions and alternatives could be made without departing from the spirit and scope of the invention, which should be determined from the appended claims.

What is claimed is:

1. An infrared sensing device, comprising:
semiconductor substrate having a face;
readout integrated circuit formed at said face of said semiconductor substrate;
a mesa of Group II-VI semiconductor material formed on said face of said semiconductor substrate;
at least one planar photovoltaic infrared detecting cell formed in said mesa; and
a conductor interconnect layer monolithically connecting said infrared detecting cell to said readout integrated circuit.

2. The infrared sensing device according to claim 1, wherein:
said conductor interconnect layer monolithically connects a common contact cell of said photovoltaic infrared detecting cell lying in one plane to a readout integrated circuit common contact cell lying in another plane, the two planes being separated by a height difference of more than 15 microns.

3. The infrared sensing device according to claim 1, wherein:
said mesa includes at least two layers of Group II-VI semiconductor material having different band gaps, and
at least one p-n junction diode of said infrared detecting cell being formed in one of said two layers of Group II-VI semiconductor material.

4. The infrared sensing device according to claim 1, further comprising:
a detector output conductively connected to said readout circuit input cell;
a detector common conductively connected to said readout circuit common cell;
said mesa having at least one sloped side; and
at least one conductive trace formed on said sloped side connecting said detector output and said first input of said readout integrated circuit.

5. The infrared sensing device according to claim 3, wherein said sloped side of said mesa has a slope angle between about 40 and 50 degrees relative to a horizontal plane.

6. An Infrared sensing device, comprising:
a readout integrated circuit fabricated on a substrate having a one degree tilt from a (100) crystal direction; and
a mesa formed on said readout integrated circuit, said mesa including:
a buffer layer;
a first layer of Group II-VI semiconductor material having a first band gap on said buffer layer;
said buffer layer functionally reducing mismatch between said readout integrated circuit and said first layer of Group II-VI semiconductor material;
a second layer of Group II-VI semiconductor material disposed on said first layer of Group II-VI semiconductor material, said second layer of Group II VI semiconductor material having a second band gap different from said first band gap;
first and second rows of infrared detecting cells,
said first row of infrared detecting cells conductively connected to a first row of signal input gates of said readout circuit; and
said second row of infrared detecting cells conductively connected to a second row of signal input gates of said readout circuit.

7. The Infrared sensing device according to claim 6, wherein said first layer of Group II-VI semiconductor material is formed of indium doped n-type HgCdTe.

8. The Infrared sensing device according to claim 6, wherein the said second layer of Group II-VI semiconductor material is formed of indium doped n-type HgCdTe with a band gap larger than the said first n-type HgCdTe layer.

9. The Infrared sensing device according to claim 6, wherein said first and second rows of infrared detecting cells include an arsenic compound at least partially extending into said first layer of Group II-VI semiconductor material layer.

10. An Infrared sensing device having at least one infrared light sensitive element, comprising:
a readout integrated circuit formed at a face of a semiconductor layer having a tilt of approximately one degree from the (100) crystal direction;
a mesa formed on a first surface of said readout integrated circuit, said mesa including:
buffer layer;
a first layer of Group II-VI semiconductor material on said buffer layer, said first layer of Group II-VI semiconductor material having a first band gap;
said buffer layer functionally reducing mismatch between said readout integrated circuit and said first layer of Group II-VI semiconductor material;
a second layer of Group II-VI semiconductor material disposed on said first layer of Group II-VI semiconductor material, said second layer of Group II-VI semiconductor material having a second band gap; and
said first band gap being different from said second band gap.

11. A monolithic infrared detector array according to claim 10, further comprising:
a first infrared detecting cell at least partially extending into said first layer of Group II-VI semiconductor material;
a second infrared detecting cell at least partially extending into said first layer of Group II-VI semiconductor material, said second infrared detecting cell not overlapping said first infrared detecting cell,
a first conductive interconnect trace formed between said first infrared detecting cell and signal input gates of said readout circuit,
a second conductive interconnect trace formed between said second infrared detecting cell and signal input gates of said readout circuit,
said mesa having first and second sloped sides;
said first conductive interconnect trace running over said first sloped side of said mesa;
said second conductive interconnect trace running over said second sloped side of said mesa.

12. A method for fabricating a monolithic infrared detector, comprising the steps of:
a) providing on a read-out integrated circuit a Si(001) surface;
b) etching the Si(001) surface to yield a dyhdride terminated smooth Si(001) surface;
c) inserting the read-out integrated circuit and clean and passivated Si(001) surface into an MBE chamber;
d) growing a buffer layer of single crystalline CdTe on the ROIC within the MBE chamber while maintaining the ROIC at a temperature less than 500 degrees C.;
e) depositing within the same MBE chamber a first layer of HgCdTe with narrow band gap on the buffer layer within the MBE chamber while maintaining the ROIC at a temperature less than 500 degrees C.; and
f) depositing within the same MBE chamber a second HgCdTe layer with a relatively wider band gap on the first layer of HgCdTe within the MBE chamber while maintaining the ROIC at a temperature less than 500 degrees C.

13. The method of claim 12, wherein the step of etching comprises the steps of:
b-1) etching the Si wafer in a diluted solution of HF:H₂0 to remove the passivation layer; and
b-2) etching the Si wafer in a concentrated solution of NH₄F to yield a dyhdride terminated smooth Si(001) surface.

14. The method of claim 12, further comprising the steps of:
g) depositing a thin CdTe cap layer on the second HgCdTe layer;
h) coating the entire structure with a photoresist;
i) selectively opening a plurality of windows in the photoresist;
j) fabricating a plurality of p-n junctions by implementing arsenic atoms through the windows selectively by ion implantation technique;
k) annealing the ROIC to activate the arsenic;
l) removing the masking photoresist layer;
m) selectively protecting the grown infrared material structure with a photoresist while leaving the remaining areas uncovered;
n) etching the uncovered areas to expose the ROIC contact pads;
o) selectively protecting the grown infrared material structure with a photoresist, leaving the rest of the areas open; and
p) etching the entire sample to produce a mesa structure with a 40 to 50 degree angle between the mesa side walls and horizontal plane.

15. The method of claim 14, wherein a solution of 4% bromine in hydrobromic acid solution is used in the step of etching to produce a mesa structure.
